(19) United States
(12) Patent Application Publication
(10) Pub. No.: US 2025/0251745 A1
(43) Pub. Date: Aug. 7, 2025

(54) EXHAUST STRUCTURE AND EXHAUST METHOD FOR FLOW RATE CONTROL DEVICE, AND GAS SUPPLY SYSTEM AND GAS SUPPLY METHOD COMPRISING SAME

(71) Applicants: FUJIKIN INCORPORATED, Osaka (JP); Tokyo Electron Limited, Tokyo (JP)

(72) Inventors: Kouji NISHINO, Osaka-shi (JP); Kaoru HIRATA, Osaka-shi (JP); Katsuyuki SUGITA, Osaka-shi (JP); Shinya OGAWA, Osaka-shi (JP); Keisuke IDEGUCHI, Osaka-shi (JP); Nobukazu IKEDA, Osaka-shi (JP); Atsushi SAWACHI, Kurokawa-gun (JP)

(73) Assignees: FUJIKIN INCORPORATED, Osaka (JP); Tokyo Electron Limited, Tokyo (JP)

(21) Appl. No.: 18/846,977

(22) PCT Filed: Mar. 15, 2023
(86) PCT No.: PCT/JP2023/010113

§ 371 Date: Apr. 17, 2025

(30) Foreign Application Priority Data
Mar. 22, 2022 (JP) 2022-045363

(51) Int. Cl. G05D 7/06; H01L 21/67

(52) U.S. Cl. CPC G05D 7/0641; H01L 21/67017

(57) ABSTRACT

An exhaust structure for a flow rate control device 10 includes a main body 11 in which a main body flow path 13 communicating a fluid inlet 13i and a fluid outlet 130 is formed, a control valve 12 provided on the main body flow path, a restriction part 14 provided downstream of the control valve, and a pressure sensor 16 for measuring a pressure between the control valve and the restriction part, a gas source 2 for supplying a gas to the flow rate control device, and an exhaust path 4 branching at a branch point A on a gas supply path between the gas source and the flow rate control device. A first valve V1 is provided in the gas supply path 3 upstream of the branch point, and a second valve V2 is provided in the exhaust path. When switching from a state of controlling the first flow rate to controlling of the second flow rate, closing the first valve V1 and opening the second valve V2 in a state where the control valve 12 is opened, to exhaust gas accumulated between the control valve and the restriction part from the exhaust path 4.

### TECHNICAL FIELD

The present invention relates to an exhaust structure and an exhaust method for a flow rate control device used in semiconductor manufacturing equipment, a chemical plant, or the like, and a gas supply system and a gas supply method using the exhaust structure and the exhaust method.

### BACKGROUND ART

In semiconductor manufacturing equipment or a chemical plant, various flow meters and flow rate control devices are utilized for flow rate control of material gas, etching gas, and the like. Among these, a pressure type flow rate control device is widely used, because it is capable of mass flow rate control of various fluids with high accuracy by a relatively simple mechanism which is a combination of a control valve and a restriction part (e.g., an orifice plate or a critical nozzle). Different from a thermal flow rate control device, the pressure type flow rate control device has an excellent flow rate control characteristic of performing stable flow rate control even when the primary side supply pressure, that is the pressure upstream of the control valve, greatly fluctuates.

There is a pressure type flow rate control device which adjusts a flow rate by controlling a fluid pressure upstream of the restriction part (hereinafter, sometimes referred to as an upstream pressure P1). When the critical expansion condition (upstream pressure P1/downstream pressure P2≥approximate 2: for argon gas) is satisfied, the flow rate of the gas flowing through the restriction part is fixed to the sound velocity regardless of the magnitude of the downstream pressure P2 downstream of the restriction part, and the mass flow rate of the gas flowing downstream of the restriction part is proportional to the upstream pressure P1. Therefore, it is possible to accurately control a flow rate by appropriately controlling the upstream pressure P1 using a control valve provided upstream of the restriction part.

### PRIOR-ART DOCUMENT

### Patent Documents

Patent literature 1: International Publication No. WO2015/064035
Patent literature 2: Japanese Laid-Open Patent Publication No. 2013-231460

### SUMMARY OF INVENTION

### Technical Problem

However, since the pressure type flow rate control device is configured to flow gas through a pore of the restriction part, the pressure of residual gas between the control valve and the restriction part does not suddenly fall, even after the opening degree of the control valve is reduced in order to reduce the flow rate. The residual gas may flow out over a relatively long time of about one second for example. Therefore, in the pressure type flow rate control device, in order to further improve the responsiveness at the time of flow rate falling, that is when changing the control flow rate from a larger flow rate to a smaller flow rate, there is a requirement that the residual gas must be discharged as soon as possible.

With respect to this requirement, Patent Literature 1 discloses a technique for rapidly reducing the gas pressure between the control valve and the restriction part when performing a so called step-down flow rate control in which the gas supply amount falls in a stepwise manner. In the pressure type flow rate control device described in Patent Literature 1, an exhaust path as a branch path is connected to a position between the control valve and the restriction part. When performing the flow rate step-down, an exhaust valve provided in the exhaust path is opened for a short period of time, so that the upstream pressure P1 is reduced more rapidly.

However, in the method described in Patent Literature 1, since an exhaust path and an exhaust valve need to be provided at a position between the control valve and the restriction part of the pressure type flow rate control device, there is a problem that the internal structure of the pressure type flow control device is inevitably complicated. Further, in the method described in Patent Literature 1, since it is not easy to add an exhaust function to an existing pressure type flow rate control device by modification, a redesigned pressure type flow rate control device is usually being used.

The present invention has been made in view of the above problems, and main object is to provide an exhaust structure and an exhaust method for a flow rate control device capable of improving responsiveness at flow rate step-down while utilizing the configuration of an existing flow rate control device, and a gas supply system and a gas supply method using the same.

### Solution to Problem

The exhaust structure for the flow rate control device according to an embodiment of the present invention includes a flow rate control device having a main body in which a main body flow path communicating a fluid inlet and a fluid outlet is formed, a control valve provided on the main body flow path, a restriction part provided downstream of the control valve, and a pressure sensor provide between the control valve and the restriction part for measuring a pressure of the main body flow path; a gas source for supplying a gas to the flow rate control device; an exhaust path branching at a branch point on a gas supply path between the gas source and the flow rate control device; a first valve disposed in the gas supply path upstream of the branch point; a second valve disposed in the exhaust path; and a control unit for controlling operation of the first valve, the second valve, and the control valve, wherein the control unit exhausts the gas accumulated between the control valve and the restriction part from the exhaust path by closing the first valve while opening the second valve, in a state where the control valve is opened, when changing from a first flow rate control to a second flow rate control.

In an embodiment, the exhaust structure is configured so as to pre-exhaust the gas between the first valve and the control valve by closing the first valve while closing the second valve and closing the control valve temporarily, before exhausting the gas between the control valve and the restriction part, when changing the flow rate from the first flow rate to the second flow rate.

In an embodiment, the exhaust structure for flow rate control device further includes a supply pressure sensor for measuring a pressure of the flow path between the control valve and the first valve, and is configured to control the opening and closing operation of the control valve based on an output of the supply pressure sensor, when changing the flow rate from the first flow rate to the second flow rate.

In an embodiment, the exhaust structure for flow rate control device further includes a tempering part disposed between the control valve and the branch point.

In an embodiment, a plurality of gas supply paths and a plurality of corresponding flow rate control devices are provided, and the first valve is provided in each of the plurality of gas supply paths, while the exhaust path including the second valve is commonly connected to the plurality of the gas supply paths.

In an embodiment, a plurality of gas supply paths and a plurality of corresponding flow rate control devices are provided, the plurality of gas supply paths and the exhaust path are formed in one flow path block, the first valve and the second valve being fixed to the one flow path block.

A gas supply system according to an embodiment of the present invention includes an exhaust structure for flow rate control device according to any one of the above-described embodiments, and is configured to exhaust the gas between the control valve and the restriction part until a pressure corresponding to the second flow rate is reached, then close the second valve, open the first valve and the control valve, and perform control at the second flow rate.

An exhaust method for flow rate control device according to an embodiment of the present invention is performed by using the exhaust structure for flow rate control device comprising a flow rate control device including a main body forming a main body flow path communicating a fluid inlet and a fluid outlet, a control valve provided on the main body flow path, a restriction part provided downstream of the control valve, and a pressure sensor provided between the control valve and the restriction part for measuring a pressure of the main body flow path; a gas source for supplying a gas to the flow rate control device, an exhaust path branching at a branch point on a gas flow path between the gas source and the flow rate control device, and the exhaust structure being configured by disposing a first valve in the gas supply path upstream of the branch point and a second valve in the exhaust path. The exhaust method includes steps of outputting a signal for changing the state from the first flow rate control to the second flow rate control; closing the first valve and opening the second valve in a state where the control valve is opened; and exhausting the fluid accumulated between the control valve and the restriction part to the exhaust device.

In an embodiment, the exhaust method of the flow rate control device includes a step of pre-exhausting the gas between the first valve and the control valve, and then opening the control valve by closing the first valve and opening the second valve while once closing the control valve temporarily, after the step of outputting a signal for changing the state from the first flow rate control to the second flow rate control, and before exhausting the gas between the control valve and the restriction part.

A gas supply method according to an embodiment of the present invention includes the exhaust method for flow rate control device, and includes a step of closing the second valve, opening the first valve and the control valve to perform control at a second flow rate after the step of exhausting the fluid accumulated between the control valve and the restriction part to the exhaust device.

### Effect of Invention

Responsiveness can be improved at the time of the flow rate step-down by utilizing the gas supply system using the exhaust structure and the gas supply method using the exhaust method for flow rate control device according to the embodiments of the present invention.

### BRIEF DESCRIPTION OF DRAWINGS

FIG. 1 is a schematic diagram illustrating the gas supply system using the exhaust structure for a flow rate control device according to an embodiment of the present invention.

FIG. 2 is a diagram illustrating a configuration example of the flow rate control device provided in the gas supply system.

FIG. 3 is a schematic diagram illustrating a gas supply system using the exhaust structure for the flow rate control device according to another embodiment of the present invention.

FIG. 4 is a diagram illustrating the valve opening and closing operation when performing the flow rate step-down operation according to the present embodiment, (a) to (d) shows the sequential steps.

FIG. 5 is a graph illustrating the temporal change in the upstream pressure P1 and the control valve opening CV when performing the flow rate step-down operation according to the present embodiment.

FIG. 6 is a diagram illustrating an example of each signal at the time of the flow rate step-down.

FIG. 7 is a flowchart illustrating a gas supply operation including the exhaust operation of the flow rate control device according to an embodiment of the present invention.

FIG. 8 illustrates an embodiment in which one common exhaust path is provided for a plurality of gas supply lines.

FIG. 9 are views illustrating an embodiment in which the gas supply path and the exhaust path for a plurality of gas supply lines are formed in one metal block, where (a) is a cross-sectional view and (b) is a plan view.

### DESCRIPTION OF EMBODIMENTS

Hereinafter, embodiments of the present invention will be described in detail with reference to the accompanying drawings, but the present invention is not limited to the embodiments described below.

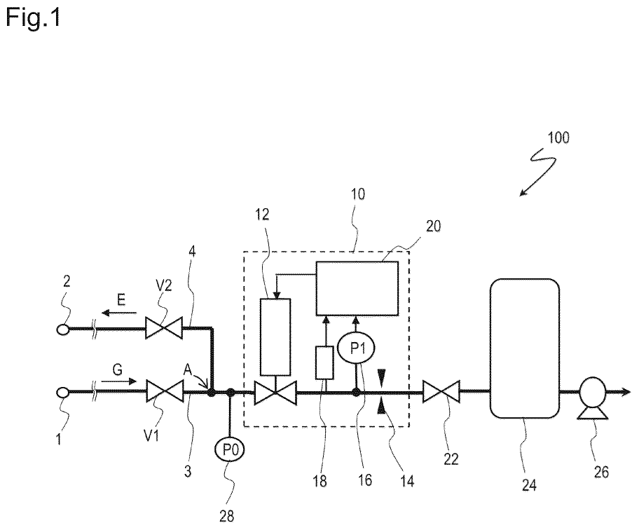

FIG. 1 illustrates a gas supply system 100 according to the present embodiment. The gas supply system 100 is capable of suppling a gas G from a gas source 1 to a process chamber 24 via a pressure type flow rate control device 10 provided in a gas supply path 3. A shut-off valve 22 is provided downstream of the pressure type flow rate control device 10 and is able to stop the gas supply to the process chamber 24. Further, a vacuum pump 26 is connected to the process chamber 24 and is able to evacuate the inside of the process chamber 24 and a flow path during gas supply. As the shut-off valve 22, for example, an AOV (Air Operated Valve) or a solenoid valve may be used and may be incorporated in the pressure type flow rate control device 10.

The pressure type flow rate control device 10 of the present embodiment includes a restriction part 14 disposed in the flow path, a control valve 12 disposed upstream of the restriction part 14, a pressure sensor 16 for detecting an upstream pressure P1 between the restriction part 14 and the control valve 12, and a temperature sensor 18 for detecting a temperature between the restriction part 14 and the control valve 12. The pressure type flow rate control device 10 may further include a pressure sensor (not shown) for measuring a downstream pressure P2 downstream of the restriction part 14. The pressure sensor for measuring the downstream pressure P2 may be provided integrally with the pressure type flow rate control device 10 or may be provided separately from the pressure type flow rate control device 10.

As the pressure sensor 16, for example, a semiconductor piezo resistive diffusion pressure sensor or a capacitance manometer is used, and as the temperature sensor 18, for example, a resistance temperature detector or a thermistor is used. As the control valve 12, for example, a piezo element driven valve (hereinafter, sometimes referred to as a piezo valve) that opens and closes a metal diaphragm valve element by a piezo actuator is used. The piezo valve is a valve (for example, a proportional valve) capable of opening to an arbitrary opening degree by adjusting a driving voltage applied to the piezo element.

As the restriction part 14, for example, an orifice plate or a sonic nozzle is used, and an aperture diameter of the restriction part 14 is set to, for example, 10 to 2000 μm. As the restriction part 14, an arbitrary flow resistor, that is, one that restricts the flow of the fluid, the pressure of the fluid, and the like is used.

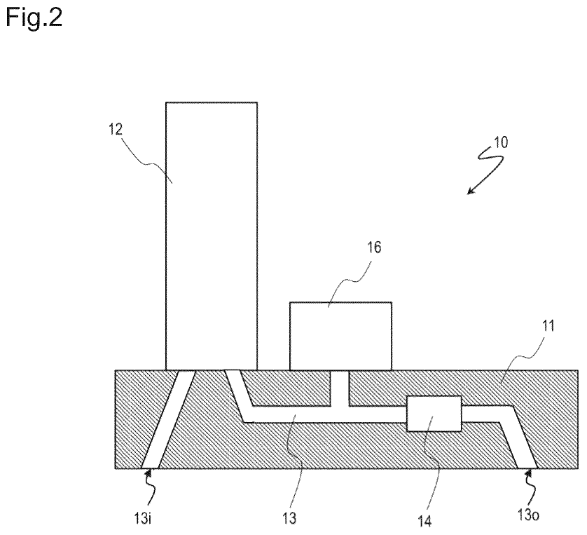

FIG. 2 illustrates an exemplary configuration of the pressure type flow rate control device 10. The pressure type flow rate control device 10 is configured to have a main body 11 formed with a main body flow path 13 communicating a fluid inlet 13i and a fluid outlet 130. The main body 11 is formed of a metal block made of, for example, stainless steel, and the main body flow path 13 is formed by combining elongated holes drilled in the metal block. The control valve 12 and the restriction part 14 are provided in the main body flow path 11. Further, a pressure sensor 16 for measuring a pressure of the main body flow path 13 between the control valve 12 and the restriction part 14 is attached to the main body 11. In FIG. 2, the temperature sensor 18 and the like shown in FIG. 1 are omitted, but the temperature sensor 18 is disposed in, for example, a bottomed hole drilled up to the vicinity of the main flow path 13.

Referring again to FIG. 1, the pressure type flow rate control device 10 also includes a control circuit 20 connected to the pressure sensor 16, the temperature sensor 18, and the control valve 12. The control circuit 20 is realized by a combination of hardware and software, including a CPU, a memory, an A/D converter, and the like provided on a circuit board, and a computer program for executing an operation to be described later.

When supplying gas to the process chamber 24, the control circuit 20 determines the flow rate using an output of the pressure sensor 16, and controls the control valve 12 so that the flow rate passing through the restriction part 14 becomes a set flow rate. More specifically, when the critical expansion condition (P1/P2≥about 2: for argon gas) is satisfied, a calculated flow rate is obtained from the output of the pressure sensor 16 according to the relationship of the flow rate Q=K1P1 (where K1 is a proportional coefficient depending on the fluid type and fluid temperature), and the control valve 12 is feedback controlled so that the calculated flow rate becomes the same as the set flow rate. In addition, when a pressure sensor (not shown) for measuring the downstream pressure P2 is provided, even under the non-critical expansion condition, the flow rate control can be performed according to the relationship of the flow rate Q=K2P2^{m}(P1−P2)ⁿ (where K2 is a proportional coefficient depending on the fluid type and fluid temperature, and the exponents m, n are values derived from the actual flow rate). The flow rate obtained by the calculation may be displayed as a flow rate output value on a display unit of an external control device.

Further, the gas supply system 100 of the present embodiment is provided with a gas supply path 3 upstream of the pressure type flow rate control device 10, and the gas supply path 3 has a first valve (gas supply valve) V1 disposed between a gas source 1 and the pressure type flow rate control device 10. In addition, an exhaust path 4 having a second valve (exhaust valve) V2 is connected to a branch point A between the first valve V1 disposed in the gas supplying path 3 and the pressure type flow rate control device 10. The exhaust path 4 is connected to an exhaust device 2, and the gas exhaust E from the gas supplying path 3 can be performed by opening the second valve V2. As the first valve V1 and the second valve V2, for example, an on-off valve having good responsiveness such as an AOV (Air Operated Valve), a solenoid valve, or an electrically operated valve is preferably used, but a valve with adjustable opening degree such as a piezo valve may also be used.

Further, a supply pressure sensor 28 for measuring a supply pressure P0 is provided in the gas supply path 3 between the first valve V1 and the pressure type flow rate control device 10. The supply pressure sensor 28 is used for checking whether the supply pressure P0 is kept sufficiently high during normal gas supply and is also used for monitoring the supply pressure P0 during a flow rate step down, which will be described later. As the supply pressure sensor 28, similarly to the pressure sensor 16, for example, a semiconductor piezo resistive diffusion pressure sensor or a capacitance manometer is used. Unlike the embodiment shown in FIG. 1, the supply pressure sensor 28 may be incorporated in the pressure type flow rate control device 10.

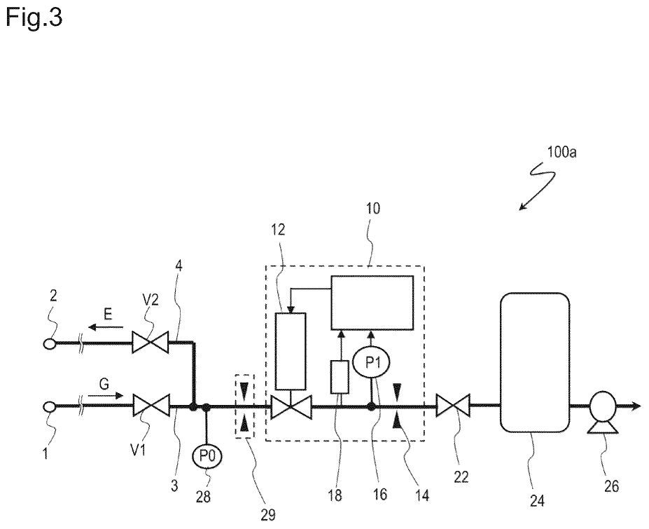

FIG. 3 illustrates a gas supply system 100a according to another embodiment. When the gas in the gas supply path 3 or between the control valve 12 and the restriction part 14 is suddenly exhausted through the exhaust path 4, the pressure P1 downstream of the control valve 12 causes a sudden pressure fluctuation. Thus, the control is performed in an unstable state, consequently, the flow rate control may become unstable. In order to prevent such a situation, as shown in FIG. 3, a tempering part 29 may be provided between the pressure type flow rate control device 10 or the control valve 12 and the branch point A for tempering (limiting) the flow of the gas at the time of exhaust to some extent. As a result, it is possible to suppress the sudden pressure fluctuation in the upstream pressure P1 and to perform a smooth flow rate control. As the tempering part 29, one having an opening area larger than that of an orifice, a sonic nozzle, or the like utilized in the restriction unit 14 may be used.

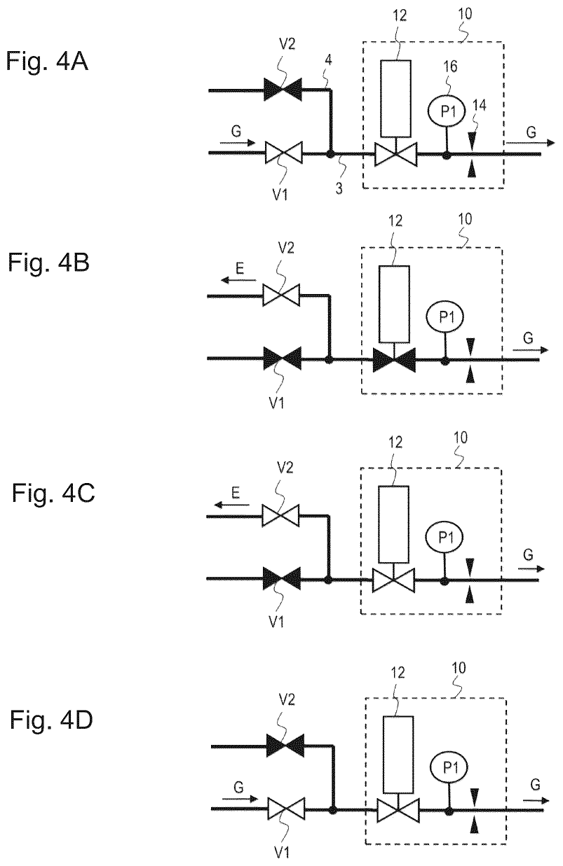

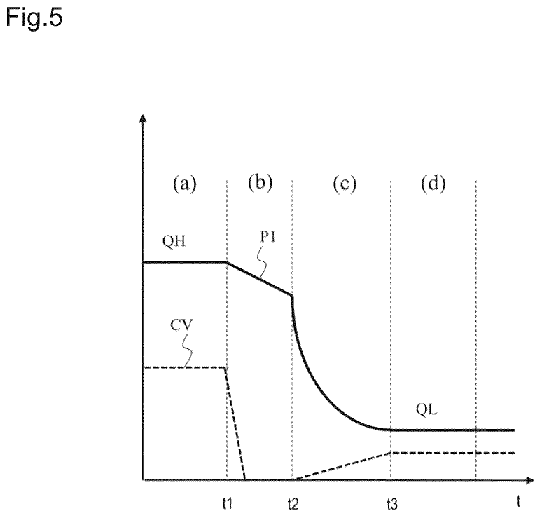

Hereinafter, the operation of the gas supply system 100 when performing the flow rate step down will be described with reference to FIGS. 4 and 5.

FIGS. 4(a) to 4(d) are diagrams sequentially illustrating the opening and closing operations of the first valve V1, the second valve V2, and the control valve 12 when the flow rate steps down from the first flow rate QH to the lower second flow rate QL. In FIG. 4, the white valve indicates that the valve is opened, and the black valve indicates that the valve is closed. In FIG. 4, the supply pressure sensor 28, the temperature sensor 18, and the control circuit 20 shown in FIG. 1 are omitted for simplicity.

Note that some or all of the components of the control circuit 20 may be provided outside the pressure type flow rate control device 10. The control circuit 20 for controlling the control valve 12 is provided inside the pressure type flow rate control device 10, while the first valve V1 and the second valve V2 may be controlled by another external control circuit. Alternatively, all controls including the control of the control valve 12 of the pressure type flow rate control device 10 may be performed from the outside. Note that the control circuit 20 built in the pressure type flow rate control device 10 and the control circuit for performing other controls are provided with communication function and cooperate function so as to be able to cooperate with each other, a control unit may be configured to include the control circuit 20 and other control circuits to perform all controls.

FIG. 5 illustrates a temporal change in the upstream pressure P1 and a temporal change in the opening degree CV of the control valve 12 with respect to the respective states shown in FIGS. 4(a) to 4(d). Here, since the upstream pressure P1 in the pressure type flow rate control device 10 is proportional to the flow rate as described above, it may be considered as the flow rate Q.

First, as shown in FIG. 4(a) and section (a) of FIG. 5, in a state where the second valve V2 is closed, while the first valve V1 and the control valve 12 are open, the gas flows at the first flow rate QH (e.g., 100% flow rate). The flow rate can be expressed as a ratio for a rated flow rate of 100%. At this time, the upstream pressure P1 also has a higher value corresponding to the first flow rate QH. The opening degree CV of the control valve 12 is also opened to a corresponding large opening degree.

In addition, when the gas flows at the first flow rate, the supply pressure P0 upstream of the control valve 12 is maintained to be sufficiently large with respect to the upstream pressure P1. On the other hand, the downstream pressure P2 downstream of the restriction part 14 is typically maintained at a vacuum pressure (e.g., 100 Torr or less), and the gas is supplied to the process chamber 24 at the first flow rate.

Next, at time t1 shown in FIG. 5, when a command is issued to change from the first flow rate QH to the second flow rate QL that is lower than the first flow rate, as shown in FIG. 4(b) and section (b) of FIG. 5, while the first valve V1 is closed and the gas supply is stopped, the second valve V2 is opened and the exhaust E is started.

Here, in the present embodiment, the control valve 12 is also closed at the start of the flow rate step down. That is, the gas between the first valve V1 and the control valve 12 is pre-exhausted by once closing the control valve 12 prior to exhausting the gas between the control valve 12 and the restriction part 14. Exhausting the flow path between the first valve V1, the second valve V2, and the control valve 12 from the exhaust path 4 in this manner results in rapidly decrease in the supply pressure P0. On the other hand, even when the control valve 12 is closed, the residual gas between the control valve 12 and the restriction part 14 flows downstream through the restriction part 14, and accordingly, the upstream pressure P1 also decreases.

As shown in FIG. 5, the opening degree CV of the control valve 12 during the pre-exhaust may be linearly decreased. Further, prior to opening the second valve V2 for pre-exhausting, it is possible to close all the valves, that is, the first valve V1, the second valve V2, and the control valve 12, and then open the second valve V2.

Then, the control valve 12 may be opened at time t2 shown in FIG. 5, when the supply pressure P0 becomes sufficiently low. As a result, as illustrated in FIG. 4(c) and section (c) of FIG. 5, the residual gas between the control valve 12 and the restriction part 14 not only flows out downstream via the restriction part 14 but also is exhausted from the exhaust path 4 via the control valve 12. Therefore, the upstream-pressure P1 drops more rapidly, and, at the same time, the flow rate of the downstream-flowing gases can be lowered more rapidly.

In order to efficiently promote the decrease in the upstream pressure P1 by using the exhaust path 4 as described above, it is conceivable to open the control valve 12 largely at the time of exhaust, and it is preferable to increase the opening degree (flow path cross-sectional area) of the control valve 12 at least more than the opening cross-sectional area of the restriction part 14. However, if the control valve 12 is opened too much, it takes a long time to adjust the opening degree of the control valve 12 when the gas flows at the second flow rate QL thereafter, which may cause an undershoot. In consideration of these, the opening degree of the control valve 12 during the exhaust operation may be arbitrarily set according to the magnitude of the first flow rate and the second flow rate, for example, ramp function control may be employed so that the opening degree of the control valve 12 gradually opens linearly as shown in section (c) of FIG. 5.

Next, as illustrated in FIG. 5, at time t3, when a satisfactory decrease in the upstream pressure P1 is confirmed, the operation is switched to the normal operation of flowing the gas at the second flow rate QL. That is, as shown in FIG. 4(d), the first valve V1 is opened to resume supplying the gas from the gas source 2, and the second valve V2 is closed to close the exhaust path 4. This operation rapidly recovers the supply pressure P0 upstream of the control valve 12.

Further, the control valve 12 shifts to feedback control based on the output of the pressure sensor 16, and the opening degree is adjusted so that the upstream pressure P1 is maintained at a pressure corresponding to the second flow rate QL. Thus, as shown in section (d) of FIG. 5, even after the time t3, it is still possible to continuously flow the gas at the second flow rate QL downstream of the restriction unit 14. In the above-described flow rate step down, since the upstream pressure P1 can be reduced more quickly by using the exhaust path 4, the responsiveness thereof can be improved.

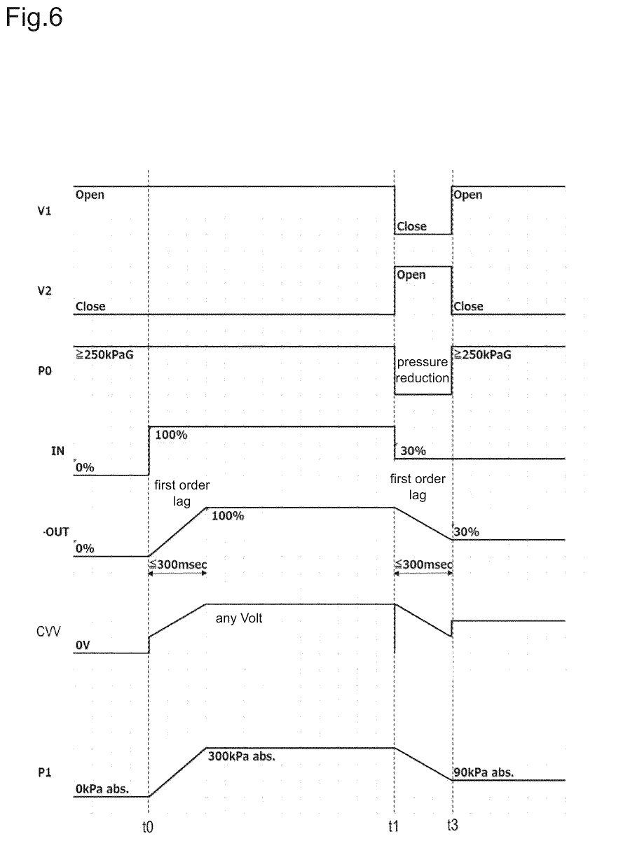

FIG. 6 is a graph illustrating an example of a flow rate control operation sequence including a flow rate step down from a first flow rate (here 100% flow rate) to a second flow rate (here 30% flow rate). In FIG. 6, V1, V2 indicates the opening and closing operation of the first valve V1 and the second valve V2, and P0 indicates the supply pressure P0 upstream of the control valve. In addition, IN and OUT indicate the input signal to the pressure type flow rate control device 10 (set flow rate signal) and the output signal (calculated flow rate signal based on the measured upstream pressure P1), respectively. Further, CVV indicates the piezoelectric drive voltage applied to the normally closed piezo valve constituting the control valve 12, and P1 indicates the upstream pressure P1 between the control valve 12 and the restriction part 14.

In the embodiment shown in FIG. 6, the control valve 12 is closed at the piezo drive voltage CVV=0V, a signal for flowing the gas at 100% flow rate is input to the pressure type flow rate control device 10 at the time to from the 0% flow rate control state in which the gas supply stops. At this time, the first valve V1 is opened, the second valve V2 is kept closed, and the supplied pressure P0 is kept at a sufficiently higher pressure (here, 250 kPa gauge pressure or higher).

On the other hand, the piezoelectric driving voltage CVV is given an initial voltage, and the piezoelectric driving voltage CVV gradually increases in accordance with the ramp-function control or the first order lag control of the target upstream pressure P1. By performing such control, it is possible to suppress the occurrence of flow overshoot due to the sudden opening of the control valve 12. As a method of controlling the control valve 12, other methods such as feedback control from the beginning may be used.

Thereafter, by the feedback control of the control valve 12, the upstream pressure P1 is kept at a constant pressure (here, 300 kPa absolute pressure) and the gas flows at a flow rate of 100%, from this status, an input signal IN for decreasing the flow rate to a flow rate of 30% is given to the pressure type flow rate control device 10 at time t1.

In the present embodiment, the first valve V1 is closed, the second valve V2 is opened, and the supply pressure P0 is depressurized. The piezo drive voltage CVV is set to 0 in an instant to close the control valve 12, and after exhausting the residual gas in the gas supply path 3 in an instant, the voltage is returned to the original voltage to open the control valve 12, and thereafter, the opening degree is gradually reduced. At this time, since the control valve 12 is open, the residual gas between the control valve 12 and the restriction part 14 are exhausted more rapidly through the exhaust path 4 via the control valve 12 and the second valve V2.

Thereafter, at time t3, when the upstream pressure P1 reaches the pressure corresponding to the second flow rate (here, 90 kPa absolute pressure), the control valve 12 is returned to the feedback control for keeping the pressure corresponding to the second flow rate. At the same time, the first valve V1 is opened, the second valve V2 is closed, and the supply pressure P0 is recovered to a sufficiently higher pressure, so that gas can continuously flows at the second flow rate thereafter.

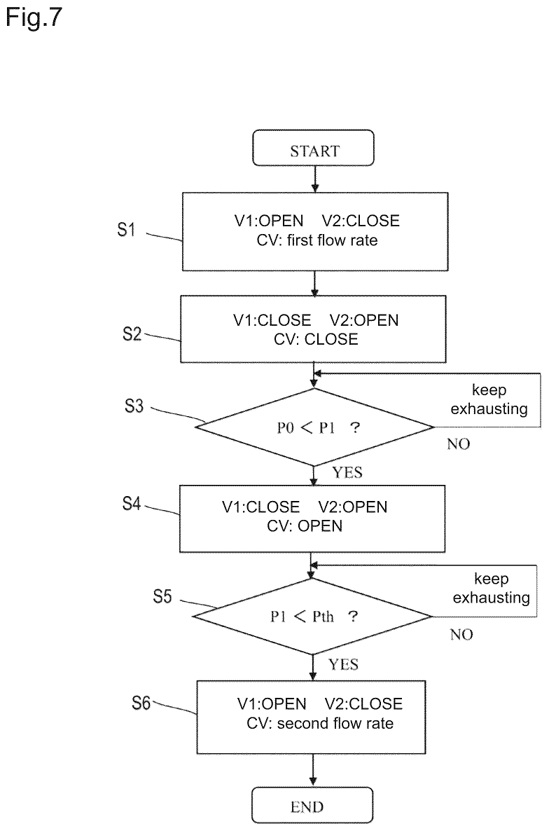

FIG. 7 is a flowchart illustrating an example of the flow rate step down control. First, as shown in step S1, in the state where the first valve V1, which is the gas supply valve, is opened, and the second valve V2, which is the exhaust valve, is closed, the control valve opening degree CV is adjusted to an opening degree corresponding to the first flow rate, and the gas flows downstream of the restriction part 14 at the first flow rate.

Here, when a command as the set flow rate signal is received to change the flow rate to the second flow rate which is smaller than the first flow rate and is not zero, as shown in step S2, the first valve V1 is closed, and the second valve V2 is opened to perform an exhausting operation. Here, the control valve opening degree CV is also closed, and the pre-exhaust of the gas upstream of the flow path between the first valve V1 and the control valve 12 is performed. It should be noted that the first valve V1 may be closed for the last short period of flowing gas at the first flow rate. As long as the upstream pressure P1 between the control valve 12 and the restriction part 14 can be kept at a desired value, the gas supply at the first flow rate can be performed immediately before the step down to the second flow rate is performed while the first valve V1 is closed to lower the supply pressure P0.

Next, in step S3, whether the supply pressure P0 has dropped sufficiently or not is determined by being compared with the upstream pressure P1. If the supply pressure P0 is smaller than the upstream pressure P1, it can be seen that opening the control valve 12 is sufficient to exhaust the residual gas to the upstream side. Thus, by controlling the opening and closing operation of the control valve 12 at the time of the flow rate step down based on the output of the supply pressure sensor 28, the exhaust of gas to the upstream side can be performed more reliably and effectively.

However, the step S3 is not necessarily required, and in such a case where the flow path volume between the first valve V1 and the control valve 12 is relatively small, or in such a case where the supplied pressure P0 rapidly decreases in a short time due to the pre-exhaust, the control valve 12 may be controlled to be closed for a predetermined short period of time without comparing the pressures in particular. Further, the supply pressure P0 does not necessarily to be lower than the upstream pressure P1, and whether or not the pre-exhaust is completed may be determined on the basis of whether or not the supply pressure P0 has decreased to a predetermined pressure. In addition, it is also possible to omit the steps S2 and S3 in which the control valve 12 is closed temporarily to perform pre-exhaust.

Next, as shown in step S4, the residual gas between the control valve 12 and the restriction part 14 is exhausted through the exhaust path 4 on the upstream side. Thus, the flow rate of the upstream pressure P1 and the flow rate of the gas flowing downstream can be rapidly reduced. In step S4, the control valve 12 may be opened to a predetermined opening degree at once or may be gradually opened to a predetermined opening degree. Further, feedback control of the control valve 12 may be continuously performed on the basis of the upstream pressure P1. This is because that the control valve 12 is considered to be kept open until the measured upstream pressure P1 drops to a pressure corresponding to the second flow rate, even in the case where the residual gas is being exhausted to the upstream side.

Then, as shown in step S5, whether the upstream pressure P1 has decreased to a threshold Pth of the upstream pressure corresponding to the second flow rate is determined. The threshold Pth may be the value of the upstream pressure P1 corresponding to the second flow rate itself or may be a threshold set to a different value. If the thresholds Pth is set small, the exhausting time to the upstream side may become longer, so that the upstream pressure P1 may be reduced more quickly, but it may also lead to undershooting due to insufficient supply pressure P0 when the gas is flowed at the second flow rate subsequently. Therefore, the threshold Pth may be set to a value that is higher than the upstream pressure P1 corresponding to the second flow rate to some extent.

Next, when sufficient decrease in the upstream pressure P1 is confirmed, as shown in step S6, while the first valve V1 is opened, the second valve V2 is closed, the supply pressure P0 is restored, the upstream gas supply state is adjusted, and the control valve opening degree CV is controlled to the opening degree corresponding to the second flow rate. Specifically, the gas can be flowed at the second flow rate to the downstream side of the restriction part 14 by feedback controlling the control valve 12 based on the output of the pressure sensor 16 that measures the upstream pressure P1.

As described above, by performing the flow rate step down using the exhaust path 4 provided upstream, it is possible to accelerate the decrease in the upstream pressure P1 and to improve responsiveness. Further, since the exhaust path 4 is relatively easy to be additionally connected to the gas supply path 3 upstream of the pressure type flow rate control device 10 by modification, so the existing pressure type flow rate control device 10 can be used, it can additionally improve responsiveness.

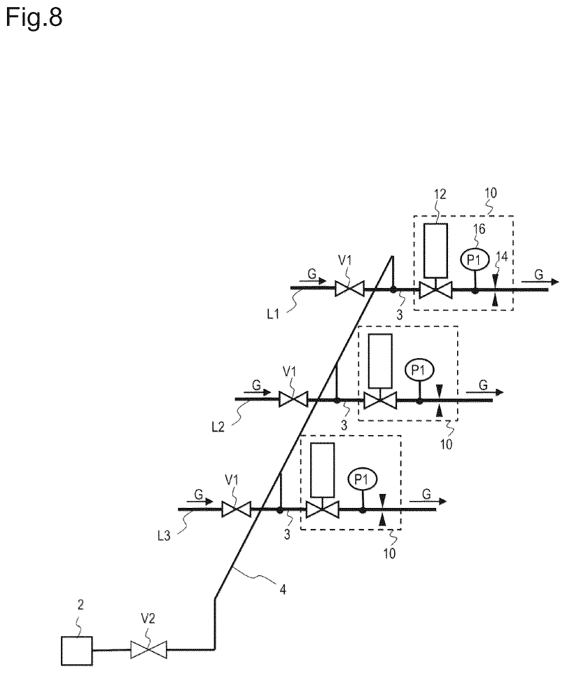

Hereinafter, a gas supply system according to another embodiment will be described. FIG. 8 illustrates an embodiment in which a common exhaust path 4 is provided for a plurality of gas supply lines L1-L3. In the gas supply system shown in FIG. 8, each gas supply path 3 of the respective gas supply line is provided with a pressure type flow rate control device 10 respectively, so that various types of gas can be supplied to the process chamber at a desired flow rate. During the period when a gas is supplied in any one of the gas supply lines, the first valves V1 and the control valves 12 in the other gas supply lines are normally closed.

On the other hand, the exhaust path 4 is commonly connected to a branch point between the first valve V1 and the control valve 12 in the respective gas supply path 3. The exhaust path 4 can be used for the upstream exhaust at the time of the flow rate step down for any of the gas supply lines L1-L3, and thus improve responsiveness.

By providing the common exhaust path 4 as described above, only one exhaust device 2, one exhaust path 4, and one second valve V2 are sufficient, so that the system configuration can be simplified, and the cost can be lowered. In addition, even when a supply pressure sensor (not shown) is provided, it may be sufficient to provide only one in the exhaust path 4 or in one of the gas supply paths 3.

Further, instead of separately providing the exhaust device 2, the vacuum pump 26 shown in FIG. 1 can also be used as the exhaust device 2. Here, the respective gas supply path L1-L3 is connected to the same process chamber 24, and the above-mentioned common exhaust path 4 for exhausting from the upstream side is connected to an exhaust system including a vacuum pump 26 connected to the process chamber 24. Further, not only in the case when a plurality of gas supply lines L1-L3 are provided as in the present embodiment, but also in the case of one-line gas supply system shown in FIG. 1, the vacuum pump 26 connected to the chamber can be used as the exhaust device 2.

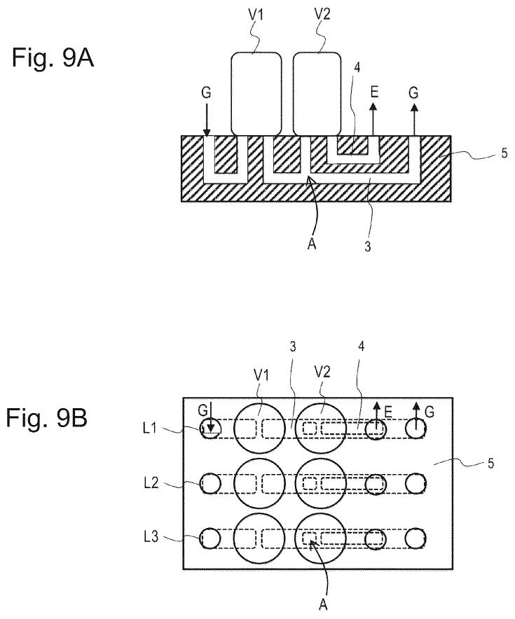

FIG. 9(a) and FIG. 9(b) illustrate an embodiment in which the gas supply path 3 and the exhaust path 4 of the plurality of gas supply lines L1-L3 are provided in one flow path block 5. The flow path block itself corresponding to the plurality of gas supply lines is disclosed in, for example, Patent Literature 2, and is used to form an integrated gas supply system.

In the present embodiment, each flow path is formed by drilling in a block made of metal (for example, stainless steel) as the flow path block 5. In addition, although a U-shaped flow path is shown in FIG. 9(a), since it is not easy to form such a flow path by drilling, in fact, each flow path can be easily formed by sealing the opening of the pore drilled from the block end face by sealing plug, or by drilling V-shaped pores extending obliquely downward from the upper surface.

As shown in FIGS. 9(a) and 9(b), the first valve V1 and the second valve V2 are fixed to the flow path block 5, the gas supply path 3 and the exhaust path 4 connected at the branch point A can be compactly formed in a plurality of lines. By providing such a flow path block 5 to precede the flow path block including a flow rate control device, the exhaust E from the upstream side can be perform while performing the supply of the gas G without problems in a plurality of lines, thus to improve the responsiveness of the flow rate step down in each line.

Embodiments of the present invention have been described above, however, various modifications are possible. For example, the first flow rate QH is 100%, but the present invention is not limited thereto. Similarly, the second flow rate QL is not limited to 30%. When the setting of the flow rate is changed from the first flow rate QH to the second flow rate QL, as long as the residual pressure is generated, the first flow rate QH and the second flow rate QL may be set to any flow rates. Further, FIG. 9(a) and FIG. 9(b) described an embodiment in which a plurality of exhaust paths 4 and the second valves V2 corresponding to the plurality of gas supply lines L1-L3 are provided in one flow path block 5, however, it may be configured so as to provide one common exhaust path 4 and one second valve V2 in one flow path block 5 by forming the exhaust path 4 extending in the width-direction commonly connected to the gas supply paths 3 as shown in FIG. 8.

### INDUSTRIAL APPLICABILITY

The exhaust structure and the exhaust method for a flow rate control device according to the embodiments of the present invention, and a gas supply system and a gas supply method using the exhaust structure and the exhaust method are used for gas supply in, for example, semiconductor manufacturing equipment.

### REFERENCE SIGNS LIST

1 Gas source
2 Exhaust device
3 Gas supply path
4 Exhaust path
5 Flow path block
10 Pressure type flow rate control device
11 Main body
12 Control valve
13 Main body flow path
13i Fluid inlet
130 Fluid outlet
14 Restriction part
16 Pressure sensor
18 Temperature sensor
20 Control circuit (control unit)
22 Shut-off valve
24 Process chamber
26 Vacuum pump
28 Supply pressure sensor
29 Relaxation portion
V1 1st valve (gas supply valve)
V2 2nd valve (exhaust valve)
100 Gas supply system

The invention claimed is:

1. An exhaust structure of a flow rate control device comprising:
the flow rate control device including a main body in which a body flow path communicating a fluid inlet and a fluid outlet is formed; a control valve provided on the main body flow path, a restriction part provided downstream of the control valve; and a pressure sensor provided between the control valve and the restriction part for measuring a pressure of the main body flow path;
a gas source for supplying a gas to the flow rate control device;
an exhaust path branching at a branch point on the gas supply path between the gas source and the flow rate control device;
a first valve disposed in the gas supply path upstream of the branch point,
a second valve disposed in the exhaust path; and
a control unit for controlling operation of the first valve, the second valve, and the control valve,
wherein the control unit exhausts the gas accumulated between the control valve and the restriction part from the exhaust path by closing the first valve and opening the second valve, in a state where the control valve is open, when changing a flow rate from a first flow rate to a second flow rate.

2. The exhaust structure for the flow rate control device according to claim 1, configured so as to pre-exhaust the gas between the first valve and the control valve by closing the first valve while opening the second valve and closing the control valve temporarily, before exhausting the gas between the control valve and the restriction part, when changing the flow rate from the first flow rate to the second flow rate.

3. The exhaust structure for the flow rate control device according to claim 1 or 2, further comprising a supply pressure sensor for measuring a pressure of the flow path between the control valve and the first valve,
wherein the exhaust structure is configured to control the opening and closing operation of the control valve based on an output of the supply pressure sensor, when changing the flow rate from the first flow rate to the second flow rate.

4. The exhaust structure for the flow rate control device according to claim 1 or 2, further comprising a tempering part disposed between the control valve and the branch point.

5. The exhaust structure for the flow rate control device according to claim 1 or 2, comprising a plurality of gas supply paths and a plurality of corresponding flow rate control devices, wherein the first valve is provided in each of the plurality of the gas supply paths, and the exhaust path provide with the second valve is commonly connected to the plurality of the gas supply paths.

6. The exhaust structure for the flow rate control device according to claim 1 or 2, comprising a plurality of gas supply paths and a plurality of corresponding flow rate control devices, wherein the plurality of the gas supply paths and the exhaust path are formed in one flow path block, the first valve and the second valve being fixed to the one flow path block.

7. A gas supply system comprising the exhaust structure for the flow rate control device according to claim 1 or 2, wherein the gas supply system is configured to exhaust the gas between the control valve and the restriction part until a pressure corresponding to the second flow rate is reached, then to close the second valve, open the first valve and the control valve, and perform control at the second flow rate.

8. An exhaust method of a flow rate control device performed by using an exhaust structure for a flow rate control device, the exhaust structure including;
the flow rate control device having a main body in which a main body flow path communicating a fluid inlet and a fluid outlet is formed; a control valve provided on the main body flow path; a restriction part provided downstream of the control valve; and a pressure sensor for measuring a pressure of the main body flow path;
a gas source for supplying a gas to the flow rate control device;
an exhaust path branching at a branch point on the gas flow path between the gas source and the flow rate control device;
a first valve disposed in the gas supply path upstream of the branch point, and a second valve disposed in the exhaust path;
the method comprising:
a step of outputting a signal for changing the state from controlling the first flow rate to controlling the second flow rate;
a step of closing the first valve and opening the second valve in a state where the control valve is opened; and
a step of exhausting a fluid accumulated between the control valve and the restriction part to the exhaust device.

9. The exhaust method for the flow rate control device according to claim 8, comprising a step of pre-exhausting the gas between the first valve and the control valve, and then opening the control valve by closing the first valve and opening the second valve while closing the control valve temporarily, after outputting a signal for changing a state from controlling the first valve to controlling the second valve, and before exhausting the gas between the control valve and the restriction part.

10. A gas supply method comprising the exhaust method for the flow rate control device according to claim 8 or 9, wherein the gas supply method further includes a step of closing the second valve and opening the first valve and the control valve to perform control at a second flow rate, after the step of exhausting the fluid accumulated between the control valve and the restriction part to the exhaust device.
